(19) United States
(12) Patent Application Publication
(10) Pub. No.: US 2016/0021775 A1
(43) Pub. Date: Jan. 21, 2016

(54) POWER ELECTRONIC MODULE, METHOD FOR PRODUCING SUCH A MODULE, AND ROTATING ELECTRICAL MACHINE OF A MOTOR VEHICLE COMPRISING SAME

(71) Applicant: VALEO EQUIPEMENTS ELECTRIQUES MOTEUR, Creteil Cedex (FR)

(72) Inventors: Guillaume Lucot, La Varenne Saint Hilaire (FR); Fabien Guerin, Chatillon (FR)

(73) Assignee: Valeo Equipements Electriques Moteur, Creteil Cedex (FR)

(21) Appl. No.: 14/772,891

(22) PCT Filed: Mar. 5, 2014
(86) PCT No.: PCT/FR2014/050497

§ 371 Date: Sep. 4, 2015

(30) Foreign Application Priority Data
Mar. 8, 2013 (FR) 1352078

(51) Int. Cl. H05K 7/02; H02K 5/22; H02K 11/00

(52) U.S. Cl. CPC H05K 7/02; H02K 11/001; H02K 5/225

(57) ABSTRACT

The power electronic module includes electronic components arranged in a casing and external connection elements having at least one power line suitable for being linked electrically to a power conductor of a power circuit of a rotating electrical machine. The casing and at least one element of a device for measuring an intensity of a current circulating in the power line form a single-piece assembly. According to particular features, the abovementioned element of the measurement device is a magnetic circuit. The magnetic circuit consists of ferrite and surrounds the power conductor.

### TECHNICAL FIELD OF THE INVENTION

The present invention relates to a power electronic module and its production method. It relates also to a rotating electrical machine of a motor vehicle comprising this power electronic module.

### TECHNOLOGICAL BACKGROUND OF THE INVENTION

These days, power electronics have replaced the electromechanical means of the past for the electrical power supply and control of the modern rotating electrical machines.

Whether single-phase or polyphase rotating electrical machines, synchronous or asynchronous, operating as motor or as generator, one or more power electronic modules control the currents and the voltages applied.

A standard equipment item of a motor vehicle consists of a reversible rotating electrical machine, that is to say one which is suitable for operating as generator and for charging a battery when it is coupled to the heat engine of the vehicle, and for operating as motor for starting, or for the supply of added mechanical power, when it is powered by the onboard electrical network.

This machine, called “alternator-starter” more often than not comprises:
a rotor comprising permanent magnets and/or a field frame into which an excitation current is brought;
a stator comprising phase windings in which phase currents circulate.

The patent application FR2886506 from the company VALEO EQUIPEMENTS ELECTRIQUES MOTEUR describes in extreme detail the mecatronics of a three-phase alternator-starter:
an excitation module forming a regulator brush-holder controlling the excitation current;
three power modules generating phase currents in motor mode or rectifying the phase currents in alternator mode;
a control module for the excitation module and the power modules.

The modules, in the form of casings provided externally with connection elements, are arranged on the rear bearing of the alternator-starter.

The casings contain electronic components, notably, most often, power transistors of MOSFET type, linked together by power lines consisting of a cut plate, notably of copper.

In this example of power modules, the power lines comprise ends which are all arranged in the vicinity of a first face of the casing.

The ends of the power lines are external to the casing and are shaped in such a way as to adapt to the ends of the phase windings.

The patent application EP2536261, also from the company VALEO EQUIPEMENTS ELECTRIQUES MOTEUR, describes another very recent example of a power module, implementing this same technique of the power lines allowing for the circulation of high intensity currents, known by the acronym IML (Insulated Molded Leadframe).

The ends of the power lines, in the form of blades folded at a right angle, protrude outside the casing for their electrical connection with the outside of the module.

A filling material, such as an epoxy resin or a silicone gel, or similar, fills the free internal space of the casing around the power components.

New refinements made to the alternator-starters by the inventive entity require the current in each phase to be measured.

This measurement is not performed by the power modules known from the prior art, even the most recent as the above examples show.

The implementation of a device for measuring the intensity of the current, such as a Hall-effect sensor in proximity to the conductor of each phase, well known in itself, raised the problem of bulk for the inventive entity, because there has to be a sensor installed for each phase. This is the problem that the inventive entity has sought to resolve.

### GENERAL DESCRIPTION OF THE INVENTION

The present invention therefore aims for the design of a power electronic module comprising electronic components arranged in a casing and external connection elements comprising at least one power line, suitable for being linked electrically to a power conductor of a power circuit of a rotating electrical machine, so as to provide a solution to the bulk problem described above.

In a general embodiment of the invention, this power electronic module is noteworthy in that its casing and at least one element of a device for measuring an intensity of a current circulating in the power line form a single-piece assembly.

This element of the measurement device is advantageously a magnetic circuit, preferably consisting of ferrite.

In a first particular embodiment of the invention, this magnetic circuit is preferably suitable for surrounding the power conductor of the rotating electrical machine.

In a second particular embodiment of the invention, this magnetic circuit preferably surrounds the power line of the power electronic module.

According to the invention, the magnetic circuit is advantageously of annular form, or, alternatively, of rectangular form.

Preferably, this magnetic circuit comprises a slit suitable for receiving a Hall-effect sensor.

In this case, benefit is derived from the fact that the casing, the magnetic circuit and this Hall-effect sensor form the single-piece assembly of the power electronic module.

The Hall-effect sensor is then advantageously soldered onto an electronic board internal to the casing.

The invention relates also to a method for producing a power electronic module exhibiting the above features, noteworthy in that the single-piece assembly is produced by overmolding.

It goes without saying that a rotating electrical machine of a motor vehicle will derive benefit from the integration of such a power electronic module.

These few essential specifications will have made obvious to those skilled in the art the advantages provided by this power electronic module compared to the prior art.

The detailed specifications of the invention are given in the following description in conjunction with the attached drawings. It should be noted that these drawings have no function other than to illustrate the text of the description and in no way constitute a limitation on the scope of the invention.

### BRIEF DESCRIPTION OF THE DRAWINGS

FIG. 1 shows a rear bearing of an alternator-starter comprising three power electronic modules, of the type affected by the invention, known from the prior art.

FIGS. 2a and 2b show in detail two examples of power electronic modules known from the prior art.

FIGS. 3a and 3b show the details of a first and a second embodiment of a power electronic module according to the invention.

### DESCRIPTION OF PREFERRED EMBODIMENTS OF THE INVENTION

In the context of the present invention, a power electronic module comprises electronic components which are arranged in a casing and connection elements accessible from the outside for its operation, these connection elements allowing for the transmission of control signals and the circulation of strong currents.

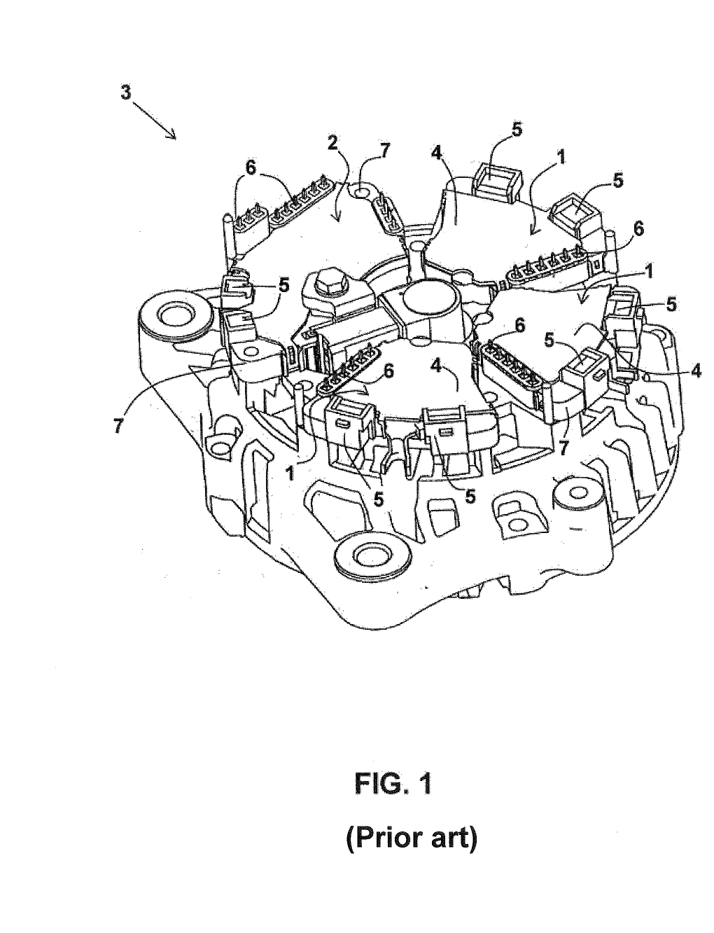

FIG. 1 shows power electronic modules 1, 2 of this type arranged on the rear bearing 3 of the three-phase alternator-starter of the prior art mentioned above.

This rear bearing 3 comprises three power modules 1 managing the phase currents and an excitation module 2 controlling the excitation current of the rotating electrical machine functioning as generator. Each power electronic module 1, 2 comprises:
a casing 4;
power connectors 5 (allowing electrical connections to the positive and negative poles of the onboard battery);
signal connectors 6 (allowing electrical links with the control module);
fixing points 7 for fixing to the frame of the machine.

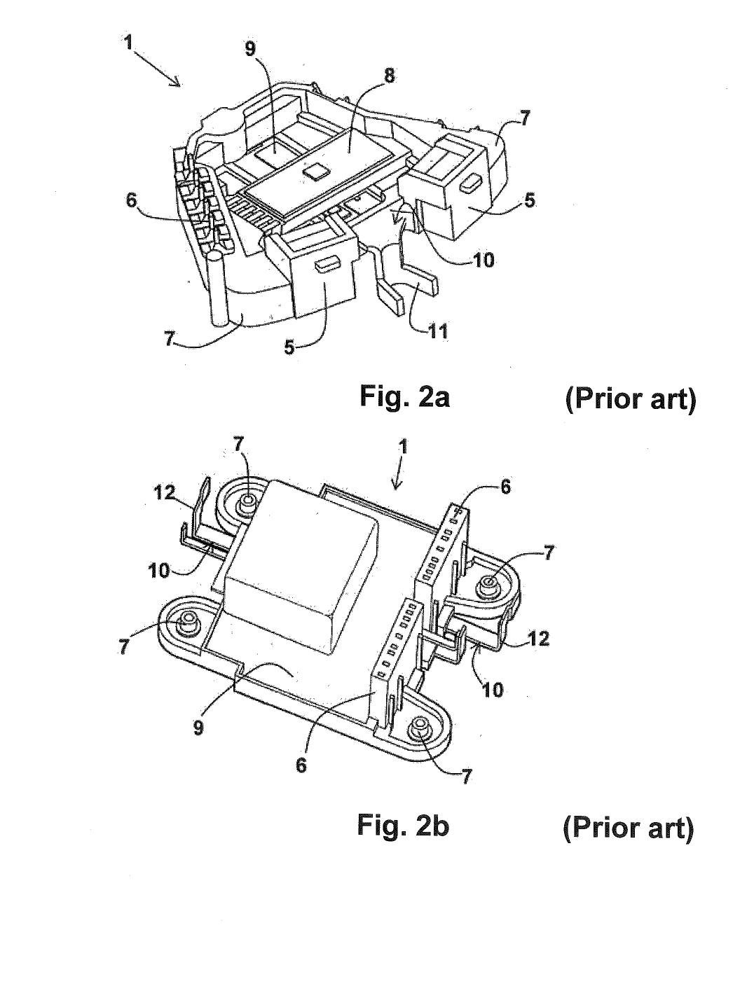

FIG. 2a shows in detail a power module 1 of the rear bearing of FIG. 1, the casing 4 of which is open, with the internal electronic components 8 linked together by a circuit of lines 9.

A power line 10 extending outside the casing 4 comprises, in this first example, a first end 11 in the form of a hook making it possible to connect, by soldering, brazing or any other suitable method, a phase wire from the stator of the electrical machine.

A second example of power electronic module 1, 2 known from the prior art is shown in FIG. 2b.

In this second example, a power line 10 extending outside of the overall enclosure of the power module 1, comprises a second end 12 in the form of a tab at right angles to the plane of the circuit of lines 9 making it possible to connect, by soldering, brazing or any other suitable method, a phase tongue 13 originating from the stator of the electrical machine.

In order to resolve the problem of bulk raised by the addition of a device for measuring the current of each phase, explained in the preamble, the inventive entity has incorporated this measurement device in the power module 1, while limiting the impact on the volume of the complete system and also on the integration of the PCB.

To do this, at least one element of the device 14, 16, 17 for measuring the intensity of the current circulating in the phase line 10 of the power module 1 forms, with the casing 4, a single-piece assembly.

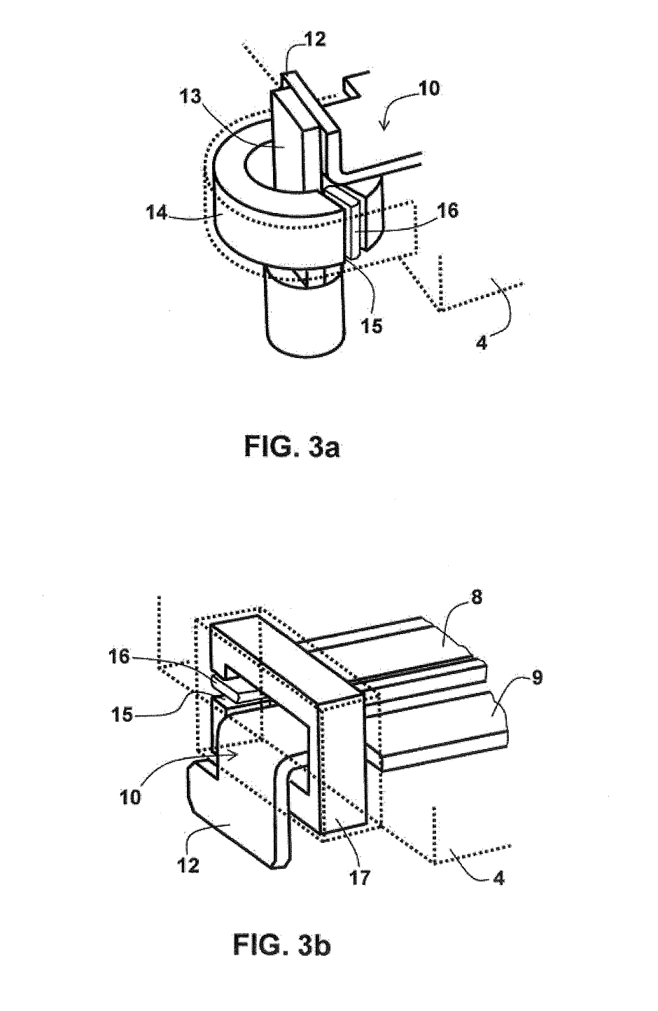

In a first preferred embodiment of the invention shown in FIG. 3a, a first magnetic circuit 14 of annular form made of ferrite is arranged in proximity to the casing 4, facing the tab-forming end 12 of the power line 10.

An axis of revolution of this ring 14, of rectangular radial section, is parallel to a longitudinal axis of symmetry of the tab 12 such that the phase tongue 13 is situated at the center of the ring 14 after connection with the power line 10.

The ring 14 includes a radial slit 15 suitable for receiving a Hall-effect sensor 16 whose signals are processed by an appropriate electronic circuit of “ASIC” type incorporated in the casing 4 so as to provide a measurement of the intensity of the current circulating in the phase circuit 13, 12, 10.

In a second preferred embodiment of the invention shown in FIG. 3b, a second magnetic circuit 17 of rectangular form made of ferrite is arranged in proximity to the casing 4, surrounding the power line 10 between the tab-forming end 12 and the casing 4.

The Hall-effect sensor 16 arranged in the slit 15, constituting a solution of continuity of the second magnetic circuit 17, is linked to the ASIC 8 incorporated in the casing 4 which ensures the processing of the signals from the sensor and supplies the required intensity measurement.

The single-piece assembly consisting of the casing 4, the first or second magnetic circuit 14, 17 and the Hall-effect sensor 16 is formed by overmolding of these constituent parts.

It goes without saying that the invention is not limited to just the preferential modes of execution described above.

Notably, the form, the section and the material of the first and second magnetic circuits 14, 17 indicated are only examples: different magnetic circuits might be better suited to other configurations of power modules 1, of power lines 10 or of the ends 13 of the phase windings.

Finally, methods for producing the power electronic module according to the invention other than overmolding do exist, notably by resin-coating of the magnetic circuit 14, 17 after the latter has been put in position.

The invention therefore encompasses all possible variant embodiments inasmuch as these variants remain within the scope defined by the claims below.

1. A power electronic module comprising:
electronic components arranged in a casing and external connection elements comprising at least one power line suitable for being linked electrically to a power conductor of a power circuit of a rotating electrical machine,
wherein said casing and at least one element of a device for measuring an intensity of a current circulating in said power line form a single-piece assembly.

2. The power electronic module as claimed in claim 1, wherein said element of said measurement device is a magnetic circuit.

3. The power electronic module as claimed in claim 2, wherein said magnetic circuit consists of ferrite.

4. The power electronic module as claimed in claim 2, wherein said magnetic circuit is suitable for surrounding said power conductor.

5. The power electronic module as claimed in claim 2, wherein said magnetic circuit surrounds said power line.

6. The power electronic module as claimed in claim 2, wherein said magnetic circuit of annular form.

7. The power electronic module as claimed in claim 2, wherein said magnetic circuit is of rectangular form.

8. The power electronic module as claimed in claim 2, wherein said magnetic circuit comprises a slit suitable for receiving a Hall-effect sensor.

9. The power electronic module as claimed in claim 8, wherein said casing, said magnetic circuit and said Hall-effect sensor form said single-piece assembly.

10. The power electronic module claimed in claim 9, wherein said Hall-effect sensor (16) is soldered onto an electronic board internal to said casing (4).

11. A method for producing a power electronic module as claimed in claim 1, wherein said single-piece assembly is produced by overmolding.

12. A rotating electrical machine of a motor vehicle comprising a power electronic module as claimed in claim 1.
